(19) United States
(12) Patent Application Publication
(10) Pub. No.: US 2007/0290244 A1
(43) Pub. Date: Dec. 20, 2007

(54) METHOD FOR PROCESSING A SCRATCHED SURFACE, PARTICULARLY A GLASS PLATE OF A SEMICONDUCTOR WAFER

(75) Inventor: Caroline Hernandez, Peyrolles (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS ROUSSET SAS, Rousset (FR)

(21) Appl. No.: 11/753,264

(22) Filed: May 24, 2007

(30) Foreign Application Priority Data
May 26, 2006 (FR) 06/04770

(51) Int. Cl. H01L 31/062; B05D 3/12; H01L 21/00; H01L 21/31

(52) U.S. Cl. 257/294; 257/E27.133; 427/240; 438/64; 257/E27.131; 438/780

(57) ABSTRACT

A method for processing a scratched surface of a material that is transparent to electromagnetic radiation includes a step of depositing onto the scratched surface at least one layer of a polymer material having substantially the same optical index as the material having the scratched surface, so as to fill in the scratches, and a step of polymerizing the polymer material. The method may be applied to the manufacture of semiconductor wafers including imagers.

### BACKGROUND OF THE INVENTION

1. Field of the Invention

The present invention relates to the processing of a scratched surface and particularly the processing of a glass surface covering a semiconductor wafer comprising CMOS imagers.

2. Description of the Related Art

Imagers produced according to the CMOS (Complementary Metal Oxide Semiconductor) technology are currently the subject of an increasing number of applications due to their low cost price in comparison with CCD (Charge Coupled Device) imagers. Such CMOS imagers were initially used to produce low resolution image sensors of mediocre quality (for example web cameras). Today, after major investment in research and development, CMOS imagers can compete with CCD imagers. The present invention is in line with an effort to develop and improve this imager technology aiming to reduce the cost with the same quality.

FIG. 1 represents an example of a module for capturing images and/or video using a CMOS imager, intended for example to be mounted into a portable device such as a mobile telephone, a camera or a video camera. The module 1 comprises a frame 2, an optical set 3, lenses 4 fitted into the set 3, an infrared filter 5 and a base 6. A semiconductor chip 100 integrating a CMOS imager 10 is disposed on the base 6 and receives the light passing through the lenses and the infrared filter.

The CMOS imager 10 comprises photosites each forming one pixel (not visible in FIG. 1). Each pixel comprises a photodiode and a control and interconnection circuit of the photodiode. The pixels are arranged as an array and a mosaic of red, green and blue filters is distributed over the pixel array, generally according to the Bayer architecture.

FIG. 2 is a schematic cross-section of the chip 100 and of the CMOS imager 10 in a region corresponding to three pixels PIX1, PIX2, PIX3. A semi-conductive substrate 15 can be distinguished into which the imager 10 is implanted, and a glass wafer 20 fixed onto the imager by means of a layer of glue 19, for example a layer of epoxy, urethane, silicone, etc.

Going from bottom to top, the imager 10 comprises layers 10-1, 10-2, 10-3, 10-4, 10-5 and microlenses L0 (L0-1, L0-2, L0-3). The layer 10-1 represents the active part of the imager and comprises photodiodes and their associated control and interconnection circuits (not detailed). The layer 10-2 is a dielectric material that fully covers the substrate 15. The layer 10-3 is a passivating layer deposited on the imager at the end of the manufacturing process. The layer 10-4 is formed by colored resins and comprises red, green or blue areas R, G, B forming the above-mentioned primary color filters, with one color filter per pixel. The layer 10-5 is an intermediate layer of resin forming a base for the microlenses L0 and providing good flatness (“planarization” layer). The microlenses L0 are arranged as a “MLA” (Microlens Array) with one microlens per pixel, and are covered by the layer of glue 19 and by the glass wafer 20.

Steps of a method for manufacturing the chip 100 are represented in FIGS. 3A to 3C. The method first of all comprises the collective manufacturing of a plurality of imagers 10i on a silicon wafer 15′, as represented in FIG. 3A. In the step shown in FIG. 3B, a large plate of glass 20′ is fixed onto the front face of the wafer by means of a layer of glue 19′ covering the entire wafer. In the step in FIG. 3C and during next steps not represented here, the wafer 15′ is turned over and is put upside down on the plate of glass 20′, its front face facing upwards, to process its rear face. This processing on the rear face comprises at least one step of thinning the wafer by mechanical abrasion (backlapping) of its rear face and a step of sawing the wafer to obtain a plurality of imager chips such as the chip 100. The rear face processing may also comprise the formation of pre-cut grooves, the formation of conductive pads, the formation of conductive bumps, etc.

During these various steps during which the wafer is put on the plate of glass 20′, the latter may be subject to friction that causes scratches 21 represented in a cross-section in FIG. 3D with a substantial enlargement. These scratches can be caused by the surface on which the wafer is put (chuck). They can also be caused by robots (handling machines) that carry different items of equipment used in the manufacturing method, upon the displacement of the basket of wafers to the “process chamber”.

These scratches cannot be accepted as they directly affect the performances of the imagers. Thus an imager chip 100 as represented in FIG. 2 and the upper glass face of which is scratched, would supply images in which the scratches would be visible.

To overcome this disadvantage, the solutions generally chosen are the following:
covering the external face of the plate of glass 20′ of the wafer with a protective layer made of resin before starting the phase of processing the rear face,
covering the bases and work surfaces with a protective material,
regularly checking the setting of the handling robots, to avoid the risks of disturbance that cause these machines to damage the wafers,
ensuring that the upper face of the plate of glass is as far as possible from the focal plane of the lenses of the optical set of the imager, so that the scratches do not appear in the images.

Such precautions are generally combined and are therefore cumulative. However, the solution involving depositing a protective layer on the plate of glass complicates the manufacturing process and increases the cost of the wafers. Moreover, due to the fragility of the protection layer, this solution introduces an additional constraint in that it limits the temperature that can be used for the processing of the rear face of the wafer. It also limits the choice of chemical products used during the different steps of processing (acids, corrosive products, etc.). Finally, the protective layer must inevitably be removed before the wafer is cut, which requires a step of removing in addition to the step of depositing this layer.

### BRIEF SUMMARY OF THE INVENTION

An embodiment of the present invention provides an alternative to this classic solution.

An embodiment of the present invention in particular provides a method that avoids the deposit and the removal of a protective layer on a plate of glass of a wafer.

For this purpose, the present invention is based on an approach to the technical problem to be solved which in a way is the antithesis of the solution to be avoided: instead of preventing scratches from appearing by systematically depositing a protective layer on each wafer during production, an embodiment of the present invention provides a method for repairing a damaged wafer by depositing a reparative layer on its scratched glass plate. Indeed, not all the wafers are systematically damaged during the manufacturing process and only a small number of wafers are concerned. In these conditions, it is less expensive to repair a scratched wafer than to ensure that no wafer will be scratched.

Furthermore, an embodiment of the present invention provides a method for erasing the scratches of a wafer by filling, by depositing on the scratched surface a reparative polymer layer having the same optical index as the scratched glass. This solution is simple to implement and does not require any long and costly operation as a step of erasing scratches by polishing for example would be.

An embodiment of the present invention thus provides a method for processing a scratched surface which must let electromagnetic radiation through, comprising a step of depositing on the scratched surface at least one layer of a polymer material having substantially the same optical index as the material constituting the scratched surface, so as to fill in the scratches, and a step of polymerizing the polymer material.

In one embodiment of the method, the scratched surface is made of glass.

According to one embodiment, the layer of polymer material is deposited by spin coating.

According to one embodiment, the polymer material is chosen from the group comprising light-sensitive or planarizing resins and glues.

According to one embodiment, the scratched surface is made of a transparent material covering a semiconductor wafer.

An embodiment of the present invention also relates to a method for manufacturing semiconductor chips each comprising a component implanted into the semiconductor, the method comprising a step of collectively implanting components onto a front face of a semiconductor wafer, a step of fixing a plate of a transparent material onto the front face of the wafer, steps of processing the wafer after the plate of transparent material has been mounted, a step of cutting the wafer into individual chips and, after the steps of processing the wafer and before cutting it into chips, a step of depositing at least one layer of a polymer material onto the external face of the plate of transparent material, the polymer material having substantially the same optical index as the transparent material.

According to one embodiment, the transparent material is glass.

According to one embodiment, the method comprises a step of controlling the external face of the plate of transparent material, and the step of depositing the layer of polymer material is only conducted if the external face of the plate of transparent material has scratches.

According to one embodiment, the steps of processing the wafer after the plate of transparent material has been mounted comprise a step of thinning the wafer by abrasion of its rear face.

According to one embodiment, the steps of processing the wafer after the plate of transparent material has been mounted comprise steps of handling the wafer by means of automated machines.

According to one embodiment, the step of implanting components onto a face of the wafer comprises implanting imagers for capturing images through the plate of transparent material.

According to one embodiment, the polymer material is chosen from the group comprising light-sensitive or planarizing resins and glues.

According to one embodiment, the polymer material is a glue used to fix the plate of transparent material onto the front face of the wafer.

An embodiment of the present invention also relates to an imager implanted onto a semiconductor chip, comprising a plate of transparent material fitted into the semiconductor chip, through which the imager receives images to be captured, the external face of the plate of transparent material being covered with at least one layer of a polymer material having substantially the same optical index as the transparent material.

According to one embodiment, the plate of transparent material is made of glass.

According to one embodiment, the polymer material belongs to the group comprising light-sensitive or planarizing resins and glues.

One embodiment of the present invention is a portable device comprising a photographic module equipped with an imager according to an embodiment of the present invention.

### BRIEF DESCRIPTION OF THE SEVERAL VIEWS OF THE DRAWINGS

These and other features and advantages of the present invention will be explained in greater detail in the following description of the process according to embodiments of the present invention given in relation with, but not limited to the following figures, in which:

FIG. 1 described above represents an image capture module for a portable device, according to prior art,

FIG. 2 described above is a schematic cross-section of an imager chip, according to prior art,

FIGS. 3A to 3C described above represent steps of a method for collectively manufacturing imagers on a silicon wafer, and FIG. 3D shows a wafer having scratches, according to prior art,

FIGS. 4A to 4E represent steps of a method for collectively manufacturing imagers on a silicon wafer comprising a step of processing scratches according to an embodiment of the present invention,

FIG. 5 represents an imager chip according to an embodiment of the present invention obtained after cutting out the wafer,

FIG. 6 represents an alternative embodiment of the step of processing scratches according to the present invention, and

FIG. 7 illustrates a portable device, according to an embodiment of the present invention.

### DETAILED DESCRIPTION OF THE INVENTION

An embodiment of the method of the present invention will be described here within the context of a method for manufacturing imagers on a semiconductor wafer.

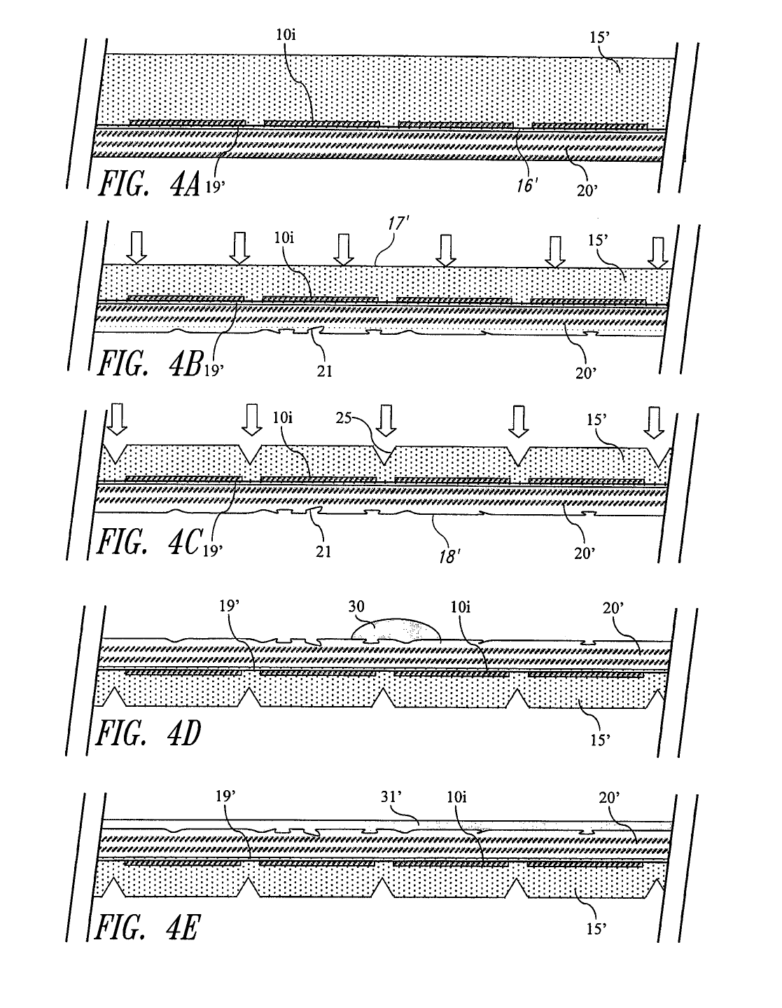

FIG. 4A shows the wafer 15′ previously described onto which a plurality of imagers 10has been implanted, a front face 16′ of the wafer 15′ being covered with the plate of glass 20′, fixed by means of the layer of glue 19′. The wafer 15′ is put upside down on a work surface (not represented) to proceed with processing steps shown in FIGS. 4B and 4C.

The step represented in FIG. 4B involves grinding and backlapping a rear face 17′ of the wafer 15′ so as to reduce its thickness, initially in the order of a few hundred micrometers and in the order of a few tens or of a hundred micrometers at the end of the process.

The step represented in FIG. 4C involves making grooves 25 on the rear face of the wafer 15′. These grooves 25 can be provided for various reasons, for example to facilitate the subsequent cutting of the wafer 15′ or to produce contacts on the rear face. The grooves 25 are generally produced by chemical etching or plasma etching.

According to an embodiment of the present invention, no protection layer is deposited on an external face 18′ of the plate of glass 20′, which is therefore exposed to a risk of scratching during the step in FIG. 4B or during the step in FIG. 4C, or even during handling steps occurring before or after each of these steps.

According to an embodiment of the present invention, a visual inspection of the wafer 15′ is performed at the end of the step in FIG. 4C, or after a step of handling the wafer 15′ occurring after the step in FIG. 4C, before the wafer 15′ is sawed to obtain imager chips.

If the plate of glass 20′ has scratches 21, as represented here in FIGS. 4B and 4C, a reparative layer made of hardenable polymer material having substantially the same optical index as the glass is deposited on the plate of glass 20′ to erase the scratches 21. In order to obtain a uniform layer, the deposit is preferably performed by spin coating. The material deposited can be liquid or gelatinous. It is then polymerized (UV polymerization or thermal polymerization).

Thus, in the step represented in FIG. 4D, a small quantity of polymer material 30, in the order of a few milliliters, is deposited on the plate of glass 20′, preferably in the centre of the wafer 15′. In the step represented in FIG. 4E, the material 30 is spread over an entire surface of the plate of glass 20′ by centrifugation. The speed of rotation of the wafer 15′ is quite low, for example 1,500 rpm. A strong acceleration, for example up to 20,000 rpm is then applied to the wafer 15′ to favor the formation of a reparative layer 31′ over the entire surface of the plate of glass 20′ while eliminating the surplus polymer material. The speed of rotation is then stabilized at a lower value, for example in the order of 2,000 to 7,000 rpm, so as to define the thickness of the reparative layer 31′ of polymer material 30. The rotation is still maintained for a certain time to enable the solvent to evaporate. The evaporation of the solvent substantially decreases the viscosity of the polymer material 30 on which the thickness of the film directly depends. As the evaporation is fast, it is necessary to make sure that the spreading time of the polymer material 30 is short. During the rotation at high speed, the largest part of the solvent contained in the material 30 evaporates and finally produces a solid film (i.e., the reparative layer 31′).

A step of baking is conducted after the step of centrifugation. This step ensures the rapid elimination of the residual solvents and the polymerization of the reparative layer 31′ and depends on the material used. A contraction (volume shrinkage) of the polymer material 30 follows, that causes a loss of thickness in the order of a fraction of a percent to a few percent, depending on the material used.

The wafer 15′ is for example heated by means of hot plates taken to a temperature in the order of one hundred to a few hundred degrees (generally speaking 100-300° C.). The duration of the heating cycle is adjusted to reach the desired solvent rate, and can be of a few minutes to more than one hour. The baking is followed by a step of cooling the wafer 15′, for example by means of plates at ambient temperature.

As an alternative, and depending on the material chosen, the polymerization step can also be conducted by exposing the wafer 15′ to ultraviolet radiation. Ultraviolet polymerization is generally shorter than thermal polymerization and only lasts a few minutes at the most.

Those skilled in the art will note that the present invention can be implemented with any type of polymer material 30 which can be deposited in the form of a liquid, then hardened, particularly light-sensitive resins (for example the “CT” resins used to manufacture microlenses of imagers), “planarizing” resins (used to form plane surfaces in microelectronics), colored resins, etc. Tests within the understanding of those skilled in the art enable the most appropriate materials to be selected depending on the nature and on the optical properties of the glass used.

Glues can also be used, and generally speaking any glue which can be polymerized in the presence of ultraviolet radiation or in the presence of heat. The material is chosen according to its optical characteristics and must have substantially the same optical index as the scratched material to neutralize the appearance of an interface diopter where the scratches 21 are situated.

According to an advantageous embodiment of the present invention, the material used to repair the scratches 21 is identical to the one used to stick the plate of glass 20′ on the wafer 15′. The glue marketed under reference OGR150THTG by Ablestick is an example of glue which can be used for this 20 purpose. In this case, the same equipment can be used both for the step of sticking the plate of glass 20′ and the step of repairing scratches 21. The cost of implementing the method according to one embodiment of the present invention is then minimal.

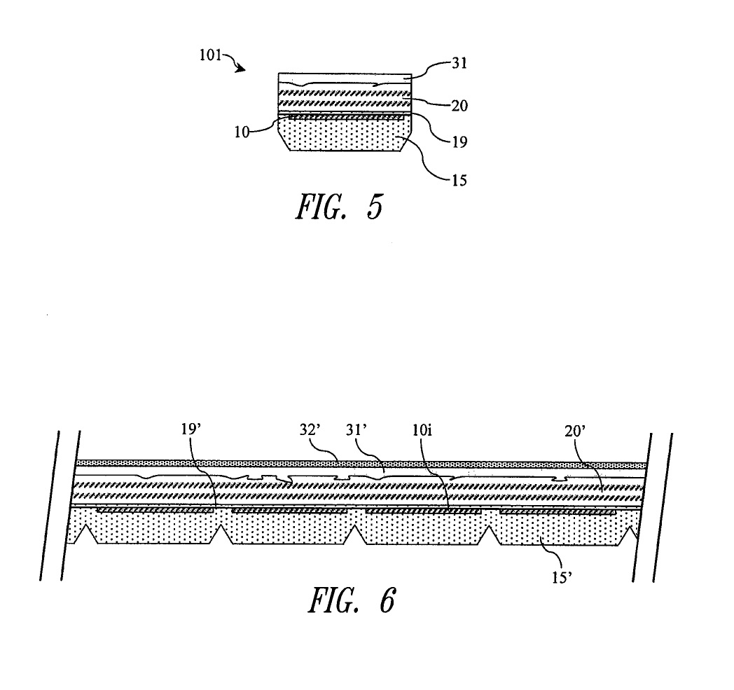

As represented in FIG. 5, an imager chip 101 according to one embodiment of the present invention, obtained by cutting the wafer, differs from the classic chip 100 represented in FIG. 2 by the presence of a reparative layer 31 on an external face 18 of the glass wafer 20.

It will be understood by those skilled in the art that various other applications and alternative embodiments of the method according to the present invention are possible. As shown in FIG. 6, at least one second reparative layer 32′ can be deposited on the wafer 15′ after the first reparative layer 31′ has been deposited.

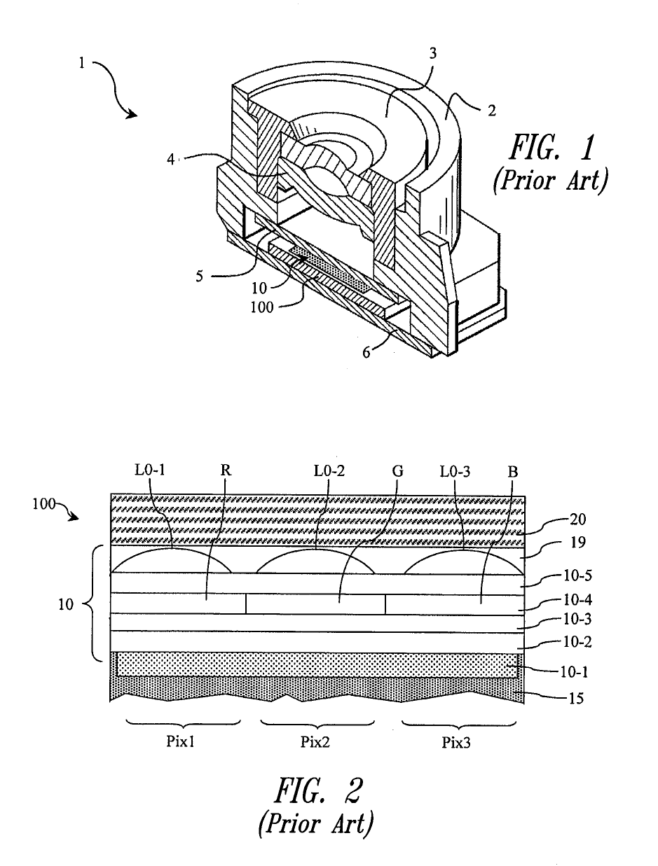

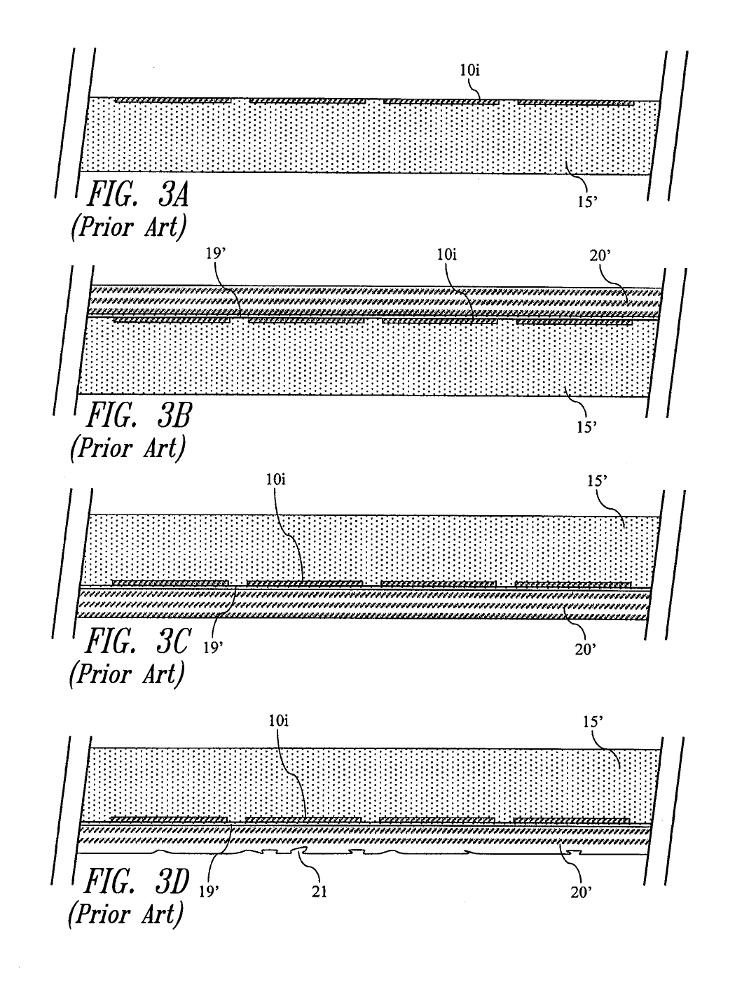

The method according to an embodiment of the present invention can be applied to any active or passive optical devices and particularly to the digital image sensors installed in portable devices comprising a photographic module of the type represented in FIG. 1, particularly mobile telephones, cameras and video cameras.

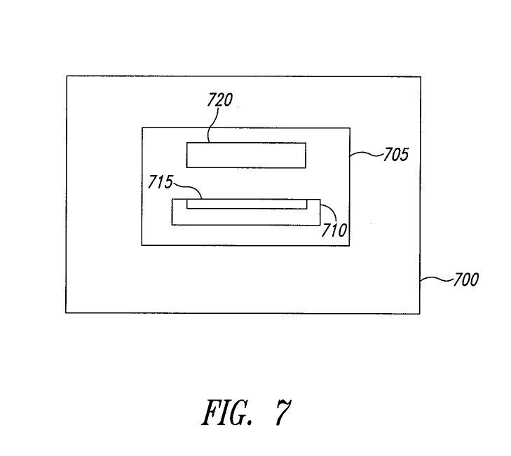

FIG. 7 illustrates a portable device 700, according to an embodiment of the invention. The portable device 700 includes a photographic module 705 and a semiconductor chip 710 integrating a CMOS imager 715. The portable device 700 may be a mobile telephone, a camera or a video camera, for example. As known to one of skill in the art, the photographic module 705 includes optical components 720, such as lenses and filters. The photographic module 705 is configured to hold the semiconductor chip 710 such that electromagnetic energy incident upon the optical components 720 is directed onto the CMOS imager 715 of the semiconductor chip 710. In one embodiment, the semiconductor chip 710 integrated with the CMOS imager 715 is the imager chip 101 (FIG. 5).

Moreover, although the method according to embodiments of the present invention has been described above in relation with the manufacturing of a semiconductor wafer comprising a plate of glass, the present invention can be applied to any transparent material, particularly Plexiglas, capable of replacing the glass.

The method according to one embodiment of the present invention is also applicable to the processing of any types of scratched surface designed to let electromagnetic radiation through, either in the visible as in the example described above, or in the infrared or the ultraviolet (or even beyond), including filtering surfaces that only let electromagnetic radiation having certain wavelengths through.

1. A method, comprising:
processing a surface of a material transparent to electromagnetic radiation, the surface including a recess, the processing including:
depositing on the surface at least one layer of a polymer material having an optical index substantially the same as an optical index of the material having the surface, so as to fill in the recess; and
polymerizing the polymer material.

2. The method according to claim 1, wherein the surface is made of glass.

3. The method according to claim 1, wherein depositing comprises spin coating on the surface the at least one layer of polymer material.

4. The method according to claim 1, wherein the polymer material is selected from the group consisting of light-sensitive resins, planarizing resins and glues.

5. The method according to claim 1, wherein the material having the surface covers a semiconductor wafer.

6. The method according to claim 1, wherein the material having the surface is a plate of transparent material, the plate of transparent material fixed to a semiconductor wafer, the semiconductor wafer having a plurality of implanted imagers.

7. The method according to claim 1, wherein the recess is a scratch.

8. A method for manufacturing semiconductor chips each having a component implanted into a semiconductor, comprising:
collectively implanting components onto a front face of a semiconductor wafer;
fixing a plate of a transparent material onto the front face of the wafer, the transparent material having an optical index; processing the wafer after the plate of transparent material has been fixed;
depositing at least one layer of a polymer material onto an external face of the plate of transparent material, the polymer material having an optical index substantially the same as the optical index of the transparent material; and
cutting the wafer into individual chips, wherein depositing is performed after processing and before cutting.

9. The method according to claim 8, wherein the transparent material is glass.

10. The method according to claim 8, further comprising controlling the external face of the plate of transparent material, and wherein depositing the at least one layer of polymer material is performed only if the external face of the plate of transparent material has scratches.

11. The method according to claim 8, wherein processing the wafer after the plate of transparent material has been fixed comprises thinning the wafer by abrasion of a rear face.

12. The method according to claim 8, wherein processing the wafer after the plate of transparent material has been fixed comprises handling the wafer by an automated machine.

13. The method according to claim 8, wherein implanting components onto the front face of the wafer comprises implanting imagers configured to capture images through the plate of transparent material.

14. The method according to claim 8, wherein the polymer material is selected from the group consisting of light-sensitive resins, planarizing resins and glues.

15. The method according to claim 8, wherein the polymer material is a glue used to fix the plate of transparent material onto the front face of the wafer.

16. An imager implanted onto a semiconductor chip, comprising:
a plate of a transparent material fitted into the semiconductor chip through which the imager receives images to be captured, the transparent material having an optical index; and
at least one layer of a polymer material covering an external face of the plate of transparent material, the at least one layer of polymer material having an optical index substantially the same as the optical index of the transparent material.

17. The imager according to claim 16, wherein the plate of transparent material is made of glass.

18. The imager according to claim 16, wherein the polymer material is selected from the group consisting of light-sensitive resins, planarizing resins and glues.

19. A portable device, comprising:
a photographic module including an imager implanted onto a semiconductor chip, the imager having:
a plate of a transparent material fitted into the semiconductor chip through which the imager receives images to be captured, the transparent material having an optical index; and
at least one layer of a polymer material covering an external face of the plate of transparent material, the at least one layer of polymer material having an optical index substantially the same as the optical index of the transparent material.

20. The portable device according to claim 19, wherein the plate of transparent material is glass.

21. The portable device according to claim 19, wherein the polymer material is selected from the group consisting of light-sensitive resins, planarizing resins and glues.
